(19) United States
(12) Patent Application Publication
(10) Pub. No.: US 2009/0046532 A1
(43) Pub. Date: Feb. 19, 2009

(54) Supply Voltage for Memory Device

(75) Inventor: Vincent Gouin, Mandelieu (FR)

Correspondence Address: BANNER & WITCOFF, LTD.;Attorneys for client 007052, 1100 13th STREET, N.W., SUITE 1200, WASHINGTON, DC, 20005-4051, US

(73) Assignee: INFINEON TECHNOLOGIES AG, Neubiberg (DE)

(21) Appl. No.: 11/840,314

(22) Filed: Aug. 17, 2007

(51) Int. Cl. G11C 5/14

(52) U.S. Cl. 365/228

(57) ABSTRACT

A device is provided including a memory cell, a first supply voltage generator, passively coupled to the memory cell, to provide the memory cell with a first supply voltage, and a second supply voltage generator, coupled to the memory cell, to provide the memory cell with a second supply voltage.

### FIELD

Aspects of the invention relate to supply voltages for memory devices.

### BACKGROUND

Memory devices are often driven by a supply voltage. In particular, RAM memory devices are usually supplied with a certain minimum voltage to avoid data loss. While access operations to the memory device require a higher supply voltage, the memory device may be driven at a lower supply voltage at times where the memory device is not accessed.

### SUMMARY

According to an illustrative embodiment, a device includes a memory cell, a first supply voltage generator and a second supply voltage generator. The first supply voltage generator is passively coupled to the memory cell and provides a first supply voltage to the memory cell. The second supply voltage generator is coupled to the memory cell and provides a second supply voltage to the memory cell.

According to a further illustrative embodiment, a device includes a memory cell, a supply voltage generator and a switch. The supply voltage generator is coupled with an output terminal to an input terminal of the memory cell, and the switch is coupled with an output terminal to the input terminal of the memory cell.

According to a further illustrative embodiment, a device includes a memory cell and a voltage generator coupled to the memory cell. The voltage generator comprises a single-signal amplifier.

According to a further illustrative embodiment, a first supply voltage is supplied to a memory cell during a first operation mode. During a second operation mode the first supply voltage and a second supply voltage are supplied to the memory cell.

According to a further illustrative embodiment, a first and a second supply voltage generator generate a first supply voltage and a second supply voltage, respectively, at their output terminals. The output terminal of the first supply voltage generator is coupled to an input terminal of a memory cell during a first operation mode, and the output terminals of the first and second supply voltage generators are coupled to the input terminal of the memory cell during a second operation mode.

### BRIEF DESCRIPTION OF THE SEVERAL VIEWS OF THE DRAWINGS

FIG. 1 schematically illustrates a device as an illustrative embodiment.

FIG. 2 schematically illustrates a device as a further illustrative embodiment.

FIG. 3 schematically illustrates a device as a further illustrative embodiment.

FIG. 4A schematically illustrates a device as a further illustrative embodiment.

FIG. 4B shows a voltage diagram associated with the function of the device of FIG. 4A.

FIG. 5 schematically illustrates a device as a further illustrative embodiment.

FIG. 6 schematically illustrates a device as a further illustrative embodiment.

FIG. 7 schematically illustrates a device as a further illustrative embodiment.

FIG. 8 schematically illustrates a device as a further illustrative embodiment.

FIG. 9 shows a voltage diagram associated with the function of the device.

FIG. 10 schematically illustrates a device as a further illustrative embodiment.

FIG. 11 schematically illustrates a device as a further illustrative embodiment.

FIG. 12 schematically illustrates a device as a further illustrative embodiment.

### DETAILED DESCRIPTION

In the following, illustrative embodiments are described with reference to the drawings, wherein like reference numerals are generally utilized to refer to like elements throughout. In the following description, for purposes of explanation, numerous specific details are set forth in order to provide a thorough understanding of one or more aspects of embodiments. It may be evident, however, to a person skilled in the art that one or more aspects of the illustrative embodiments may be practiced with a lesser degree of these specific details. In other instances, known structures and devices are shown in block diagram form in order to facilitate describing one or more aspects of the illustrative embodiments. The following description is therefore not to be taken in a limiting sense, and the scope of the application is defined by the appended claims.

The following description relates to memory devices and to memory cells in particular. The memory cell described in the following may be a single memory cell or may be implemented in an array of similar memory cells being controlled commonly by a memory periphery. Furthermore the memory cell may also be one of a plurality of single memory cells or may be implemented with arrays of memory cells being controlled commonly by associated memory peripheries. In particular, the one or more memory cells may be random access memory (RAM) cells, for example static random access memory (SRAM) cells or dynamic random access memory (DRAM) cells. The memory cell as set out throughout the description may be provided with different supply voltages to perform various tasks according to different possible operation modes associated with the memory. Such tasks may include data access tasks, for example read-write access or delete access, and data retention. For RAM cells, supplying a voltage causes the memory cells to consume power associated with a DC current which may be present in the memory cells. The strength of the DC current and in consequence the consumed power within the memory cell may vary with the magnitude of the supplied voltage.

Operation modes associated with the operational state of a memory cell may include a data access mode and a data retention mode which may be characterized by the absence of data access operations. In a data retention mode the memory periphery may be partially or completely switched off. During the data retention mode the supply voltage of the memory cell may be lower than during a data access mode or another operation mode so that the data retention mode may be a particular low power operation mode. In a low power operation mode the supply voltage may be adjusted to a level where data that may be stored in the memory cell will be essentially retained and where the DC current flowing through the memory cell is lowered in comparison to the DC current flowing through the memory cell in a data access mode or other operation modes. The operation mode of a memory cell may be controllable by a memory periphery or any other device suitable to control memory cells.

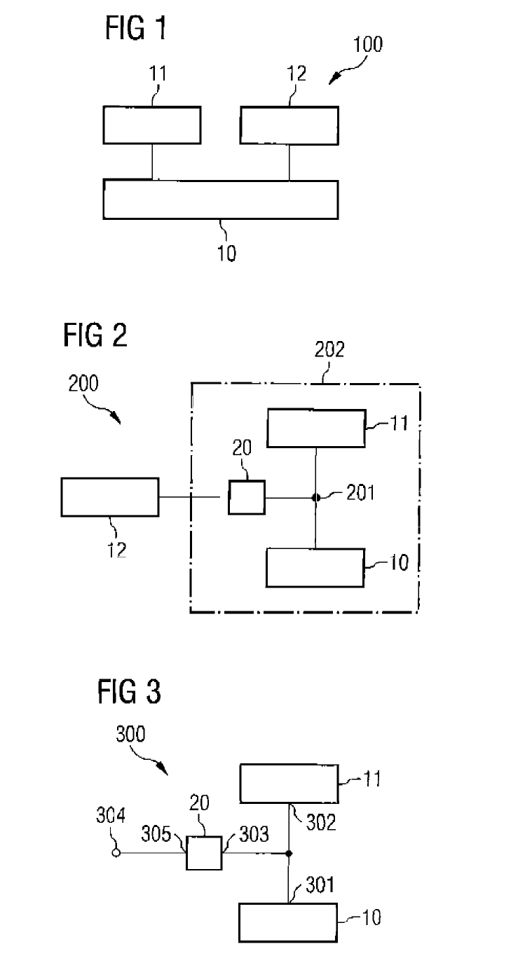

FIG. 1 schematically illustrates a device 100 as an illustrative embodiment. A memory cell 10 is coupled to a first supply voltage generator 11 via a first connection. The first supply voltage generator 11 may be coupled directly to a supply voltage input of the memory cell 10. That is, an output terminal of the first supply voltage generator 11, which is configured to provide a first supply voltage generated by the first supply voltage generator 11, may be wired to the supply voltage input of the memory cell 10. The coupling of the first supply voltage generator 11 to the memory cell 10 may be provided in such a way that the potential difference between the potential at the output terminal of the first supply voltage generator 11 and the potential at the supply voltage input of the memory cell 10 is zero or very small. Alternatively, the first supply voltage generator 11 may be coupled passively to the memory cell 10 wherein passively describes a coupling where passive electrical devices may be arranged in the voltage path between the first supply voltage generator 11 and the memory cell 10. In particular, the voltage drop along the passive electrical devices may be proportional to the first supply voltage supplied by the first supply voltage generator 11. The voltage drop may, for example, be zero or essentially zero. Passive electrical devices may include wires, in particular metal wires, resistors, inductors, capacities, resistive loads and similar devices. The first supply voltage generator 11 may be coupled to the memory cell 10 in such a way that a supply voltage generated by the first supply voltage generator 11 influences the potential at the supply voltage input of the memory cell 10 during a data retention operation mode and/or a low power operation mode of the memory cell 10. In particular, the first supply voltage generated by the first supply voltage generator 11 may be supplied to the supply voltage input of the memory cell 10. The first supply voltage generator 11 may be configured to be in an active state, i.e. to generate the first supply voltage, regardless of the operation mode of the memory cell 10.

The memory cell 10 is further coupled to a second supply voltage generator 12 which generates a second supply voltage. The second supply voltage may be provided at the supply voltage input of the memory cell 10. The second supply voltage may alternatively be provided at a voltage input of the memory cell 10 different from the supply voltage input of the memory cell 10 where the first supply voltage generated by the first supply voltage generator 11 is supplied to the memory cell 10. The first supply voltage may be lower than the second supply voltage.

FIG. 2 schematically illustrates a device 200 as an illustrative embodiment. The memory cell 10, the first supply voltage generator 11 and the second supply voltage generator 12 are configured in the same way as described above in connection with FIG. 1. In FIG. 2 the first supply voltage generator 11 is coupled to the memory cell 10 via a first node 201. The second supply voltage generator 12 is coupled to the first node 201 via a switch 20. The switch 20 may be controllable according to the operation mode of the memory cell 10. In particular, the switch 20 may be used in such a way that during a first operation mode the second supply voltage generator 12 is connected to the first node 201 and that during a second operation mode the second supply voltage generator 12 is disconnected from the first node 201. The first operation mode may be a normal operation mode, for example a data access mode of the memory cell 10, and the second operation mode may be a data retention mode and/or a low power operation mode of the memory cell 10.

In FIG. 2 the first supply voltage generated by the first supply voltage generator 11 and the second supply voltage generated by the second supply voltage generator 12 may be supplied to the first node 201 during the first operation mode. In some implementations the first supply voltage may be lower than the second supply voltage, so that during the first operation mode the second supply voltage may override the first supply voltage at the first node 201. Consequently, the magnitude of the voltage supplied to the memory cell 10 during the first operation mode may correspond to the magnitude of the second supply voltage, whereas during the second operation mode the magnitude of the voltage supplied to the memory cell 10 may correspond to the magnitude of the first supply voltage. The second operation mode may be a low power operation mode.

The first supply voltage generator 11, the memory cell 10, the first node 201 and the switch 20 may, in some illustrative embodiments, be integrated in a semiconductor chip 202 whereas the second supply voltage generator 12 may be arranged outside the semiconductor chip 202.

FIG. 3 schematically illustrates a device 300 as an illustrative embodiment. The memory cell 10 and the first supply voltage generator 11 are configured in the same way as described above in connection with FIG. 1. The first supply voltage generator 11 has an output terminal 302 which is coupled to an input terminal 301 of the memory cell 10. The coupling is provided in such a way that during normal use of the device 300 the output terminal 302 is constantly coupled to the input terminal 301. The first supply voltage generator 11 may be configured to provide a first supply voltage at the output terminal 302 which is supplied to the input terminal 301 of the memory cell 10. A switch 20 may be arranged in such a way that an output terminal 303 of the switch 20 may be coupled to the input terminal 301 of the memory cell 10.

Furthermore, an input terminal 305 of the switch 20 may be coupled to a supply voltage input terminal 304 of the device 300. The supply voltage input terminal 304 may in some implementations be used to receive a second supply voltage supplied from outside the device 300. The switch 20 may be controllable in such a way that during a first operation mode the supply voltage input terminal 304 is connected to the input terminal 301 of the memory cell 10 and that during a second operation mode the supply voltage input terminal 304 is disconnected from the input terminal 301 of the memory cell 10. The first operation mode may be a normal operation mode, for example a data access mode of the memory cell 10, and the second operation mode may be a data retention mode and/or a low power operation mode of the memory cell 10.

In FIG. 3 the first supply voltage generated by the first supply voltage generator 11 and the second supply voltage received at the supply voltage input terminal 304 of the device 300 may be supplied to the input terminal 301 of the memory cell 10 during the first operation mode. In some implementations the first supply voltage may be lower than the second supply voltage, so that during the first operation mode the second supply voltage may override the first supply voltage at the input terminal 301 of the memory cell 10. Consequently, the magnitude of the voltage supplied to the memory cell 10 during the first operation mode may correspond to the magnitude of the second supply voltage, whereas during the second operation mode the magnitude of the voltage supplied to the memory cell 10 may correspond to the magnitude of the first supply voltage.

The memory cell 10, the first supply voltage generator 11, the switch 20 and the supply voltage input terminal 304 may be integrated in the same semiconductor chip. The supply voltage input terminal 304 may be an input terminal of the semiconductor chip, which can be accessed from outside the semiconductor chip.

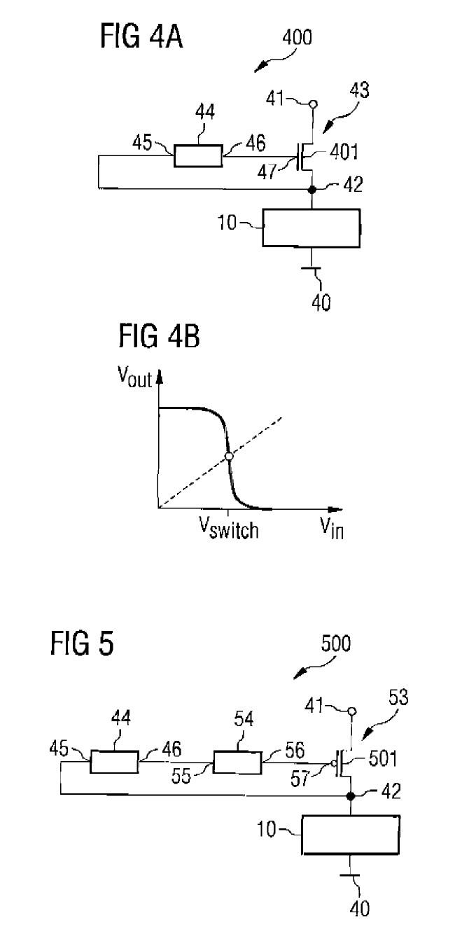

FIG. 4A schematically illustrates a device 400 as an illustrative embodiment. A memory cell 10 has a ground potential input terminal which is coupled to a ground potential 40. The memory cell 10 is further coupled to a first node 42 at an input terminal. The device 400 includes a supply voltage source 41 which is coupled to the current path 401 of a first transistor 43. The supply voltage source 41 is configured to generate a supply voltage which may be similar in magnitude to a voltage used to supply the memory cell 10 during a data access operation mode. The current path 401 of the first transistor 43 is coupled to the first node 42. The gate terminal 47 of the first transistor 43 is coupled to an output terminal 46 of a first inverting stage 44. The first inverting stage 44 further includes an input terminal 45 which is coupled to the first node 42. The first inverting stage 44 may be configured as a single-signal amplifier. In particular, the first inverting stage 44 may have a first trigging voltage. The transistor 43 may be a MOS transistor; in particular, it may be an NMOS transistor.

During a data retention mode and/or a low power operation mode of the memory cell 10, the device 400 may function as follows. If the voltage at the input terminal of the memory cell 10 is lower than the first trigging voltage of the first inverting stage 44, the first inverting stage 44 provides a signal of a logically high level at the output terminal 46. This signal is provided at the gate terminal 47 of the NMOS transistor 43. The current path 401 of the transistor 43 is then switched on causing the voltage at the input terminal of the memory cell 10 to rise due to the connection to the supply voltage source 41. If the voltage at the input terminal rises above the level of the first trigging voltage of the first inverting stage 44, the first inverting stage 44 will provide a signal of a logically low level at the output terminal 46 causing the current path 401 of the transistor 43 to switch off and hence the voltage at the input terminal of the memory cell 10 to stop rising. This way the voltage at the input terminal of the memory cell 10 may be kept at an essentially constant level. This level may be determined by the first trigging voltage of the first inverting stage 44.

FIG. 4B shows a voltage diagram of the voltage at the output terminal 46 of the first inverting stage 44 of the device 400. If the voltage Vᵢₙ at the input terminal 45 of the first inverting stage 44 is lower than the trigging voltage V_{switch} of the first inverting stage 44, the voltage Vₒᵤₜ at the output terminal 46 of the first inverting stage 44 is set to a logically high level. If the voltage Vᵢₙ at the input terminal 45 of the first inverting stage 44 is equal to the trigging voltage V_{switch} of the first inverting stage 44, the voltage Vₒᵤₜ at the output terminal 46 of the first inverting stage 44 is set to V_{switch}. If the voltage Vᵢₙ at the input terminal 45 of the first inverting stage 44 is higher than the trigging voltage V_{switch} of the first inverting stage 44, the voltage Vₒᵤₜ at the output terminal 46 of the first inverting stage 44 is set to a logically low level. The voltage interval around the trigging voltage V_{switch} along which the voltage Vₒᵤₜ at the output terminal 46 of the first inverting stage 44 drops from a logically high level to a logically low level as the voltage Vᵢₙ at the input terminal 45 of the first inverting stage 44 is increased may be very narrow. The trigging voltage V_{switch} may be adjusted to voltage requirements of the memory cell 10 during a data retention mode.

FIG. 5 schematically illustrates a device 500 as an illustrative embodiment. The memory cell 10, the ground potential 40, the first node 42, the supply voltage source 41, the first transistor 53 having a current path 501 and a gate terminal 57, and the first inverting stage 44 having an input terminal 45 and an output terminal 46 are configured similar to the respective elements of the device 400 shown in FIG. 4A. The device 500 may additionally include a second inverting stage 54 which is coupled with an input terminal 55 to the output terminal 46 of the first inverting stage 44 and which is coupled with an output terminal 56 to the gate terminal 57 of the first transistor 53. The transistor 53 may be a MOS transistor; in particular, it may be a PMOS transistor. The second inverting stage 54 may be a single-signal amplifier and it may have a second trigging voltage.

During a data retention mode and/or a low power operation mode of the memory cell 10, the device 500 may function as follows. If the voltage at the input terminal of the memory cell 10 is lower than the first trigging voltage of the first inverting stage 44, the inverting stage 44 provides a first signal with a logically high level at the output terminal 46. This first signal is provided at the input terminal 55 of the second inverting stage 54. Due to the logically high level of the first signal the second inverting stage 54 provides a second signal with a logically low level at the output terminal 56 of the second inverting stage 54. This second signal is provided at the gate terminal 57 of the PMOS transistor 53. The current path 501 of the transistor 53 is then switched on causing the voltage at the input terminal of the memory cell 10 to rise due to the connection to the supply voltage source 41. If the voltage at the input terminal of the memory cell 10 rises above the level of the first trigging voltage of the first inverting stage 44, the first inverting stage 44 will provide a first signal of a logically low level at the output terminal 46 causing the second inverting stage 54 to provide a second signal of a logically high level which in turn causes the current path 501 of the transistor 53 to switch off and hence the voltage at the input terminal of the memory cell 10 to stop rising. This way the voltage at the input terminal of the memory cell 10 may be kept at an essentially constant level. The first and the second trigging voltage may be chosen so that the aforementioned level may be mainly determined by the first trigging voltage of the first inverting stage 44.

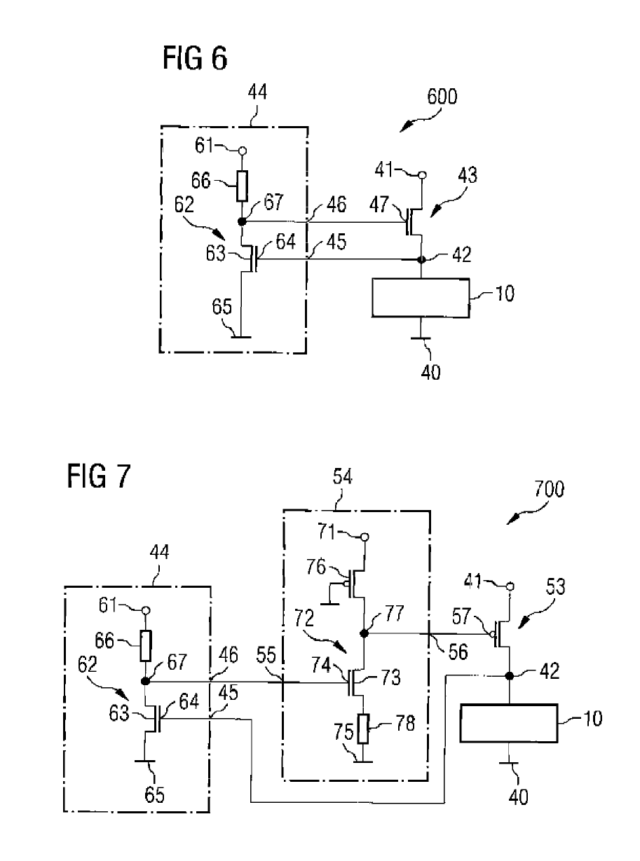

FIG. 6 schematically illustrates a device 600 which is an implementation of the device 400 shown in FIG. 4A. What is shown in FIG. 6 is an illustrative embodiment of the first inverting stage 44 in connection with the memory cell 10, the first supply voltage source 41 and the first transistor 43. The first inverting stage 44 may include a second supply voltage source 61, a second transistor 62, a first ground potential terminal 65, a first resistive load 66 and a second node 67. The second transistor 62 has a gate terminal 64 which is coupled to the input terminal 45 of the first inverting stage 44. The current path 63 of the second transistor 62 is arranged between the second node 67 and the first ground potential terminal 65 which is connected to a ground potential. The second supply voltage source 61 is coupled to one end of the first resistive load 66 which in turn is coupled to the second node 67 with another end. The second node 67 is coupled to the output terminal 46 of the first inverting stage 44.

The second transistor 62 may be a MOS transistor; in particular it may be an NMOS transistor which may have a switching voltage that corresponds to the first trigging voltage of the first inverting stage 44. The second supply voltage source 61 may be associated with the supply voltage source 41 and may provide the same supply voltage to the first inverting stage 44 as the supply voltage source 41 provides to the memory cell 10. The resistive load 66 may be a resistor or a MOS transistor. The ground potential connected to the first ground potential terminal 65 may the same potential as the ground potential 40 connected to the ground potential input terminal of the memory cell 10. The first trigging voltage of the first inverting stage 44 may be tuned to be at a threshold voltage Vt of the first transistor 43 plus a margin. In particular, it may be tuned to be at the data retention voltage limit of the memory cell 10 plus a margin.

FIG. 7 schematically illustrates a device 700 which is an implementation of the device 500 shown in FIG. 5. What is shown in FIG. 7 is an illustrative embodiment of the first inverting stage 44 and the second inverting stage 54 in connection with the memory cell 10, the first supply voltage source 41 and the first transistor 53. The first inverting stage 44 may be configured similar to the embodiment of the first inverting stage 44 shown in FIG. 6. The second inverting stage 54 may include a third supply voltage source 71, a third transistor 72, a second ground potential terminal 75, a second resistive load 76, a third node 77 and a third resistive load 78. The third transistor 72 has a gate terminal 74 which is coupled to the input terminal 55 of the second inverting stage 54. The current path 73 of the third transistor 72 is arranged between the third node 77 and the third resistive load 78 which is in turn coupled to the second ground potential terminal 75 which is connected to a ground potential. The third supply voltage source 71 is coupled to one end of the second resistive load 76 which in turn is coupled to the third node 77 with another end. The third node 77 is coupled to the output terminal 56 of the second inverting stage 54.

The third transistor 72 may be a MOS transistor; in particular it may be an NMOS transistor which may have a switching voltage that corresponds to the second trigging voltage of the second inverting stage 54. The third supply voltage source 71 may be associated with the supply voltage source 41 and may provide the same supply voltage to the second inverting stage 54 as the supply voltage source 41 provides to the memory cell 10. The second resistive load 76 may be a resistor or a MOS transistor. The third resistive load 78 may be a resistor or a MOS transistor. In particular, the third resistive load 78 may be configured in such a way that the sensitivity of the regulated voltage at the input terminal of the memory cell 10 with respect to deviations of the supply voltage provided by the supply voltage source 41 is lowered. The ground potential connected to the second ground potential terminal 75 may be the same potential as the ground potential 40 connected to the ground potential input terminal of the memory cell 10. The second trigging voltage of the second inverting stage 54 may be tuned to be higher than the first trigging voltage of the first inverting stage 44. In particular, it may be tuned to be at such a level that the regulated voltage at the input terminal of the memory cell 10 is mainly determined by the first trigging voltage of the first inverting stage 44.

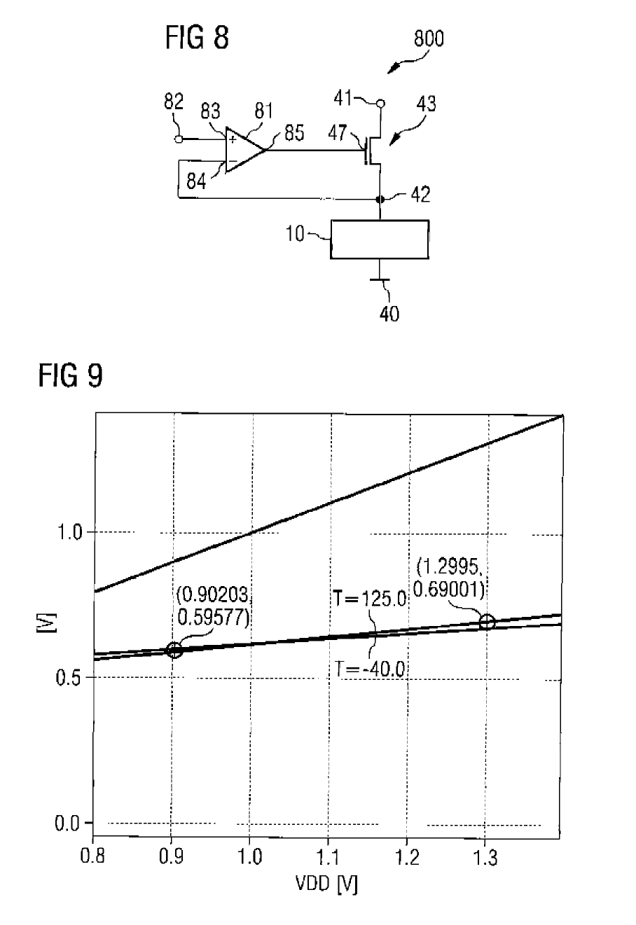

FIG. 8 schematically illustrates a device 800 as an illustrative embodiment. The device 800 includes a memory cell 10 having a ground potential input terminal connected to a ground potential 40 and an input terminal coupled to a first node 42, a first supply voltage source 41, a transistor 43 and an operational amplifier 81. The memory cell 10, the first node 42, the first supply voltage source 41 and the transistor 43 are configured as the respective elements of the device 400 shown in FIG. 4A. The operational amplifier 81 may have a non-inverting input 83 coupled to a voltage reference source 82, an inverting input 84 coupled to the first node 42 and an output terminal 85 coupled to the gate terminal 47 of the first transistor 43.

During a data retention mode and/or a low power operation mode of the memory cell 10, the device 800 may function as follows. If the voltage at the input terminal of the memory cell 10 is lower than a reference voltage provided by the voltage reference source 82, the operational amplifier 81 provides a signal of a logically high level at the output terminal 85. This signal is provided at the gate terminal 47 of the NMOS transistor 43. The current path of the transistor 43 is then switched on causing the voltage at the input terminal of the memory cell 10 to rise due to the connection to the supply voltage source 41. If the voltage at the input terminal rises above the level of the reference voltage of the operational amplifier 81, the operational amplifier 81 will provide a signal of a logically low level at the output terminal 85 causing the current path of the transistor 43 to switch off and hence the voltage at the input terminal of the memory cell 10 to stop rising. This way the voltage at the input terminal of the memory cell 10 may be kept at an essentially constant level. This level may be determined by the reference voltage coupled to the operational amplifier 81.

FIG. 9 shows a voltage diagram associated with the function of the device 700. What is shown on the horizontal axis of the diagram is the voltage level of the supply voltage source 41, which may deviate from a normal level which may be set to 1.2 V. The upper line shows the voltage at the input terminal of the memory cell 10 if there is no regulation element according to one of the illustrative embodiments in FIGS. 4 to 8. The relationship between the voltage at the input terminal of the memory cell 10 and the voltage supplied by the supply voltage source 41 is linear and the proportionality coefficient is essentially 1. The two lower lines show the dependency of the regulated voltage at the input terminal of the memory cell 10 with one of the regulating elements as illustrated in one of the FIGS. 4 to 8. The slightly steeper lower line shows this dependency for a temperature of the device 700 of T=125° C., the slightly more gently inclined line shows this dependency for a temperature of the device 700 of T=−40° C. In both cases the situation is similar. The regulated voltage at the input terminal of the memory cell 10 is around 0.6 V, if the supply voltage of the supply voltage source 41 is around 0.9 V, and the regulated voltage at the input terminal of the memory cell 10 is around 0.7 V, if the supply voltage of the supply voltage source 41 is around 1.2 V. Therefore, in this illustrative embodiment, the deviations of the regulated voltage at the input terminal of the memory cell 10 may be up to four times lower than the deviations of the unregulated voltage at the input terminal of the memory cell 10. For example, if the unregulated supply voltage is set to 1.2 V at the input terminal of the memory cell 10, the DC leakage current in the memory cell is 130 μA. However, if the supply voltage is regulated to 0.67 V at the input terminal of the memory cell 10, the DC leakage current is reduced to 53 μA. In this setup the regulation circuit can be driven with an operation current of 4 μA. Therefore, the total DC leakage current is reduced by a factor of 2 with a regulated supply voltage in contrast to an unregulated voltage source. It should be noted that the data and measurements shown in the diagram of FIG. 9 are merely an example for one embodiment. For other types of memory cells and regulation circuits according to illustrative embodiments as shown in the FIGS. 4 to 8, the data may take on different values from the ones shown here.

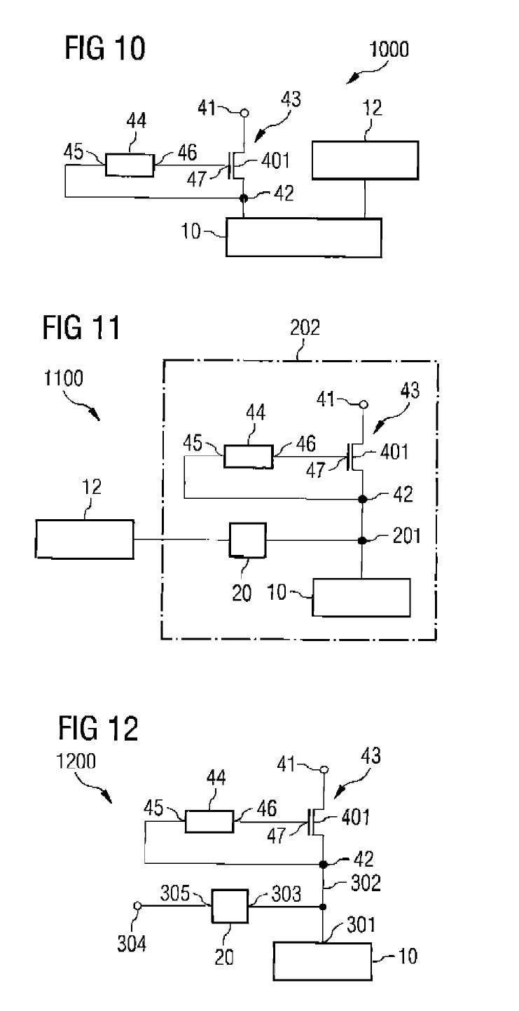

FIG. 10 schematically illustrates a device 1000 as an illustrative embodiment. The device 1000 includes a memory cell 10 and a second supply voltage generator 12 similar to the respective ones of FIG. 1. The first supply voltage generator 11 is embodied similar to the supply voltage circuit connected to the memory cell 10 as shown in FIG. 4A.

FIG. 11 schematically illustrates a device 1100 as an illustrative embodiment. The device 1100 includes a memory cell 10, a second supply voltage generator 12 and a switch 20 similar to the respective ones of FIG. 2. The first supply voltage generator 11 is embodied similar to the supply voltage circuit connected to the memory cell 10 as shown in FIG. 4A.

FIG. 12 schematically illustrates a device 1200 as an illustrative embodiment. The device 1200 includes a memory cell 10, a supply voltage input terminal 304 and a switch 20 similar to the respective ones of FIG. 3. The first supply voltage generator 11 is embodied similar to the supply voltage circuit connected to the memory cell 10 as shown in FIG. 4A.

It should be noted that the embodiment of the first supply voltage generator 11 as illustratively depicted in FIGS. 10, 11 and 12 may also be configured in a way similar to the supply voltage generation circuits shown in the FIGS. 5 to 8.

As one skilled in the art may immediately recognize, the illustrative embodiments shown in FIGS. 4 to 8 generate a “virtual” supply voltage source, i.e. the supply voltage supplied by a supply voltage source is regulated to an essentially constant lower level so that the supply voltage which is supplied to the input terminal of a memory cell is lower than the supply voltage supplied by a supply voltage source. A skilled person will notice that analog setups of regulation circuits according to the illustrative embodiments shown in FIGS. 4 to 8 are possible to provide a “virtual” ground potential. That is, the ground potential coupled to an analog regulation circuit according to the illustrative embodiments shown in FIGS. 4 to 8 is regulated to an essentially higher level so that the ground potential which is supplied at a ground potential input terminal of a memory cell is higher than the ground potential supplied to the analog regulation circuit according to the illustrative embodiments shown in FIGS. 4 to 8. Without departing from the spirit and the scope of the invention, one skilled in the art may provide the necessary obvious changes to the illustrative embodiments shown in FIGS. 4 to 8 to translate the “virtual” supply voltage source to a “virtual” ground potential.

In addition, while a particular feature or aspect of an embodiment may have been disclosed with respect to only one of several implementations, such a feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. The terms “coupled” and “connected”, along with derivatives may have been used. It should be understood that these terms may have been used to indicate that two elements co-operate or interact with each other regardless of whether or not they are in direct physical or electrical contact. Furthermore, it should be understood that embodiments may be implemented in discrete circuits, partially integrated circuits or fully integrated circuits or programming means.

1. A device, comprising:
a memory cell;
a first supply voltage generator, passively coupled to the memory cell, to provide the memory cell with a first supply voltage; and
a second supply voltage generator, coupled to the memory cell, to provide the memory cell with a second supply voltage.

2. The device of claim 1, wherein the first supply voltage is lower than the second supply voltage.

3. The device of claim 1, further comprising
a first node for coupling the first supply voltage generator to the memory cell, and
a switch for coupling the second supply voltage generator to the first node.

4. The device of claim 3, wherein the switch couples the second supply voltage generator to the first node during a normal operation mode and decouples the second supply voltage from the first node during a low power operation mode.

5. The device of claim 3, wherein the first supply voltage generator comprises a transistor and a first inverting stage to control the transistor.

6. The device of claim 5, wherein the first inverting stage comprises a first single-signal amplifier.

7. The device of claim 5, wherein a current path of the transistor is coupled to the first node.

8. The device of claim 5, wherein an input terminal of the first inverting stage is coupled to the first node.

9. The device of claim 5, wherein the first supply voltage generator further comprises a second inverting stage arranged between the first inverting stage and the transistor.

10. A device, comprising:
a memory cell having an input terminal;
a supply voltage generator having an output terminal coupled to the input terminal of the memory cell; and
a switch having an output terminal coupled to the input terminal of the memory cell.

11. The device of claim 10, further comprising a supply voltage input terminal coupled to an input terminal of the switch.

12. The device of claim 10, wherein the device has at least two operation modes and a switching state of the switch depends on the operation mode.

13. The device of claim 10, wherein the supply voltage generator comprises a transistor and a first inverting stage to control the transistor.

14. The device of claim 13, wherein the first inverting stage comprises a first single-signal amplifier.

15. The device of claim 13, wherein a current path of the transistor is coupled to the input terminal of the memory cell.

16. The device of claim 13, wherein an input terminal of the first inverting stage is coupled to the input terminal of the memory cell.

17. The device of claim 13, wherein the supply voltage generator further comprises a second inverting stage arranged between the first inverting stage and the transistor.

18. The device of claim 10, further comprising an integrated circuit in which the memory cell, the supply voltage generator and the switch are implemented.

19. A device, comprising:
a memory cell;
a voltage generator coupled to the memory cell, wherein the voltage generator comprises a first single-signal amplifier.

20. The device of claim 19, wherein the voltage generator further comprises a transistor being controlled by the first single-signal amplifier.

21. The device of claim 19, wherein a current path of the transistor is coupled to an input terminal of the memory cell.

22. The device of claim 19, wherein an input terminal of the first single-signal amplifier is coupled to an input terminal of the memory cell.

23. The device of claim 19, wherein the voltage generator comprises a second single-signal amplifier.

24. A method, comprising:
supplying a first supply voltage to a memory cell during a first operation mode; and
supplying the first supply voltage and a second supply voltage to the memory cell during a second operation mode.

25. (canceled)

26. A method, comprising:
generating by a first supply voltage generator a first supply voltage at an output terminal of the first supply voltage generator;
generating by a second supply voltage generator a second supply voltage at an output terminal of the second supply voltage generator;
coupling the output terminal of the first supply voltage generator to an input terminal of a memory cell during a first operation mode; and
coupling the output terminals of the first and second supply voltage generators to the input terminal of the memory cell during a second operation mode.

27. (canceled)
